(19) United States
(12) Patent Application Publication
(10) Pub. No.: US 2007/0273564 A1
(43) Pub. Date: Nov. 29, 2007

(54) Rapidly Queryable Data Compression Format For Xml Files

(75) Inventor: Anthony Morel, Shanghai (CN)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/596,705

(22) PCT Filed: Dec. 17, 2004
(86) PCT No.: PCT/IB04/52842

§ 371 Date: Jun. 22, 2006

(30) Foreign Application Priority Data
Dec. 30, 2003 (CN) 200310124520.5

(51) Int. Cl. H03M 7/30

(52) U.S. Cl. 341/87

(57) ABSTRACT

A method and device for XML compression with easy querying are provided. An XML file is parsed with a SAX-parser, useless characters such as tabulators and white spaces are removed, indicating data marks are inserted, LZ-77 compression is applied, and finally the data are Huffman-encoded and packed in data blocks. The indicating marks are used to search in the compresed file for tags or literals in the document, based e.g. on alphabetical order. The indicating marks consist of a special character such as a tab and an XML comment; hence they are XML-compatible. The organization of the compressed file in independent data blocks facilitates rapid querying and partial decompression of the compressed file.

### BACKGROUND ART

The present invention relates to a method and apparatus for data compression and decompression, and particularly, to a method and apparatus for XML (Extensible Markup Language) data compression and decompression.

XML is a text format, which is becoming more and more popular in data exchange. More and more standards, e.g. multimedia field, MPEG-7 and TV-Anytime, are using XML text format to represent data.

XML is a redundant format, i.e. the way XML represents data and structures leads to a relatively large text. Therefore, data compression needs to be carefully considered for transmission or storage. The most common compression method is Zlib, e.g. the best known zip (.zip files) and gzip (.gz files). It is based on Huffman, LZ77 or both.

In the prior art, a compression device compresses the XML data and sends the compressed XML data to a decompression device, which decompresses the compressed XML data and conducts analysis therefor.

FIG. 1 is a structural diagram of a compressor in the prior art. Compressor 100 comprises LZ77 encoder 102, Huffman encoder 104 and block packer 106. Compressor 100 compresses the XML data on the basis of Zlib format.

First, Compressor 100 receives the XML data; LZ77 encoder 102 encodes the XML data according to LZ77 algorithm, generating a bunch of codewords and literals. Said literals comprise the bytes from the XML data that cannot be compressed. One codeword could convert the data previously met in the XML data, namely the redundant data, into a sequence of bytes. A typical codeword comprises length and pitch, wherein the length is the length of the sequence met before, and the pitch is the space from the beginning of the sequence in the bytes to the current byte.

Huffman encoder 104 performs Huffman-encoding to the codewords and literals, outputs a sequence of codes of different lengths and generates a Huffman list.

Block packer 106 obtains a Huffman list from Huffman encoder 104, packing the data into blocks, each of which could use different Huffman lists or even does not need LZ77-encoding and Huffman-encoding at all. Here the packing has three possibilities: bypass compressing, using default Huffman list and using conventional Huffman list. The three possibilities are based on actual compression ratio and average amount of information. Each block begins with a block header. In the end, the compressed XML data is outputted and sent to the decompression device.

FIG. 2 is a structural diagram of the decompressor and analyzer in a decompression device of the prior art. Decompressor 200 decompresses the compressed XML data, obtaining the XML data. Decompressor 200 comprises block header decoder 202, Huffman decoder 204 and LZ77 decoder 206.

Block header decoder 202 decodes the compressed XML data, obtaining a Huffman list and codes and/or literals of different lengths. Huffman decoder 204 decodes the compressed XML data again, obtaining codewords and literals, and in the end, being sent to LZ77 decoder 206 for decoding, obtaining the XML data.

Analyzer 210 has a Simple Application Programming Interface (SAX) for the XML data, for SAX-analyzing the XML data to obtain event-type and event-data. Here the SAX is actually a standard for processing the XML data. It is very simple, thus being very fast. SAX processes the XML data in sequence, so it matches well with the Zlib-based in-sequence decompressor 200. SAX is a concept based on event, which is generated for the entity met by SAX-analyzing during the sequential processing of the XML data. The type of analyzer 210 event is indicated by the type of the event taking place, thus the analyzer 210 could analyze and process the event data accordingly and obtain the analyzed XML data.

Before the SAX-analyzing, the system merely takes the XML data as a sequence of literals (i.e. the compressor does not presume the property of the data); but after the SAX-analyzing, different XML entities such as elements and non-elements (literals) are distinguished. Therefore, the output after SAX-analyzing does not comprise individual literal, but a sequence of events, and each event corresponds to an entity formed of a plurality of different literals in the XML data.

In the prior art, retrieving special data from a large compressed file is a burden to the receiver, but it is preferable to perform compression in large XML data than in small XML data, particularly in the domain of expensive bandwidth (e.g. broadcasting), and the optimization of compression efficiency is of great importance. Furthermore, if the target receiver does not store, it will be impossible to store all data in one database in a decompression format. At most, it keeps the data in a compression format or waits until the data being transmitted again. Therefore, devices with large amount of resources in the prior art, e.g. large storage capability, could not directly work on large XML files, while devices with limited resources, e.g. small storage capability, could not store data in a decompression format or database format. They could only retrieve data on the basis of compressed files.

### CONTENTS OF THE INVENTION

Regarding the problems in the prior art, the present invention provides a method and apparatus for XML data compression and decompression.

The present invention provides a method for XML data compression. First, receiving and encoding the XML data; then, packing the encoded XML data into a number of data blocks; in the end, inserting indicating data between said data blocks to obtain compressed XML data, and said indicating data is for identifying particular data.

The present invention provides another method for XML data compression. First, receiving the XML data; then, inserting indicating data to the XML data, and said indicating data is for identifying particular data; in the end, compressing the XML data containing indicating data to obtain the compressed the XML data.

The present invention provides a method for XML data decompression. First, receiving the compressed XML data, which contains indicating data; then, decompressing the compressed XML data, and obtaining said indicating data during the decompressing process; in the end, discarding the corresponding decompressed XML data according to said indicating data.

The present invention provides another method for XML data decompression. First, decompressing the compressed XML data to obtain decompressed XML data; then, obtaining an indicating data from the decompressed XML data, and said indicating data is for identifying particular data; in the end, discarding the corresponding decompressed XML data according to said indicating data.

The present invention avoids analyzing irrelated data in the XML data, thus accelerating the analyzing process and quickening the operation speed of the receiver. As it processes only the related part in the XML data, so XML data with relatively larger size could be processed, while all the XML information to be transmitted could be portioned into one small block of data in the relatively larger XML data, and this is far better than processing one large block of data in small XML data, because the former uses Zlib for compression much better than the latter, thus saving bandwidth.

Other purposes and achievements of the present invention will become apparent, and complete understanding of the present invention can be achieved if reference is made to the following illustrations of the drawings and appended claims.

### DESCRIPTION OF FIGURES

The present invention is elaborately explained with reference to the drawings through embodiments, wherein:

FIG. 1 is a structural diagram of a compressor in the prior art;

FIG. 2 is a structural diagram of the decompressor and analyzer in a decompression device of the prior art;

FIG. 3 is a structural block diagram of the compressor of an embodiment of the present invention;

FIG. 4 is a flowchart of the compression method of an embodiment of the present invention;

FIG. 5 is a structural diagram of the decompression device of an embodiment of the present invention;

FIG. 6 is a flowchart of the decompression method of an embodiment of the present invention;

FIG. 7 is a structural block diagram of the compression device of another embodiment of the present invention;

FIG. 8 is a flowchart of the compression method of another embodiment of the present invention;

FIG. 9 is a structural block diagram of the decompression device of another embodiment of the present invention;

FIG. 10 is a flowchart of the decompression method of another embodiment of the present invention.

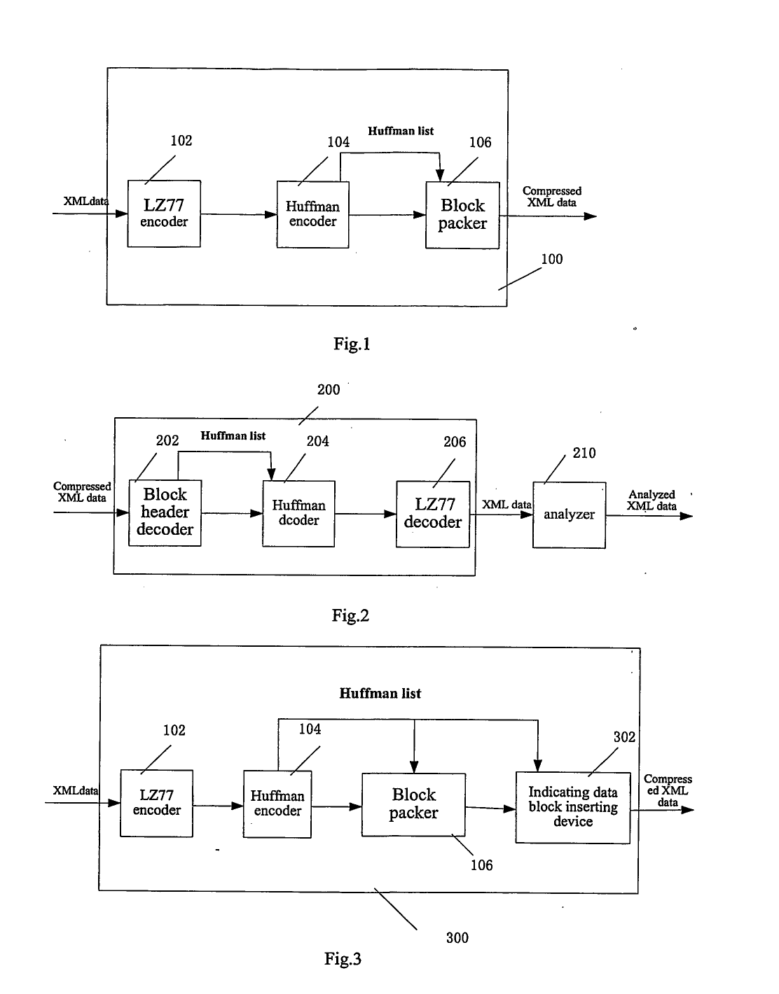

In all the drawings, the same reference number represents the same or similar feature and function.

### DETAILED EMBODIMENTS

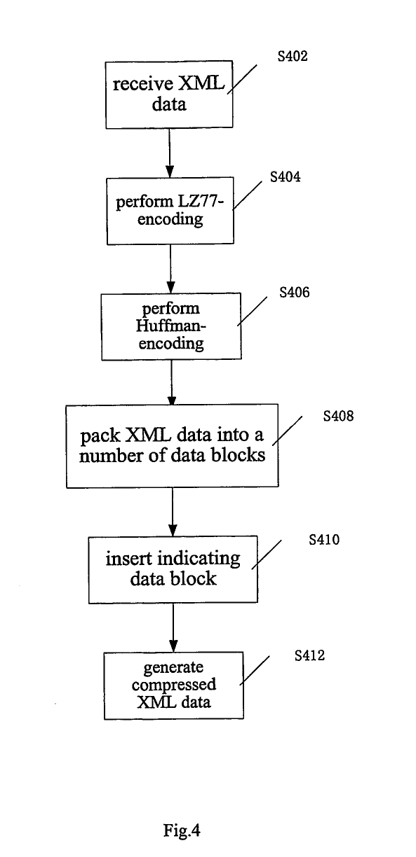

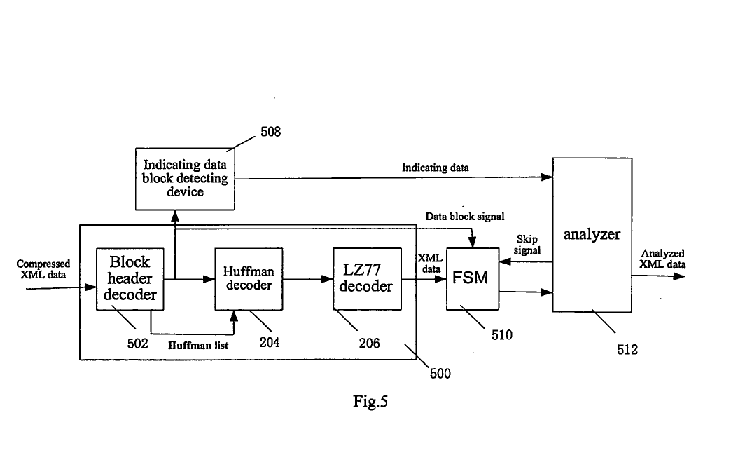

FIG. 3 is a structural block diagram of the compressor of an embodiment of the present invention. The compressor 100 comprises a LZ77 encoder 102, a Huffman encoder 104, a block packer 106, and an indicating data block inserting device 302.

LZ77 encoder 102 performs LZ77-encoding to XML data, and it may also acts as a receiving device for receiving the XML data. Huffman encoder 104 performs Huffman-encoding to the LZ77-encoded XML data, and provides Huffman list at the same time. LZ77 encoder 102 and Huffman encoder 104 together could form an encoding device for encoding the XML data.

Block packer 106 packs the Huffman-encoded XML data into a number of data blocks according to the Huffman list, and block header of each data block has partial Huffman list.

Indicating data block inserting device 302 inserts the indicating data between said data blocks according to the Huffman list to obtain the compressed XML data. Said indicating data is located in a null data block, for identifying particular data.

FIG. 4 is a flowchart of the compression method of an embodiment of the present invention. First, receiving XML data (step S402), e.g. the received XML data is:
<Entry><Word>Aback</Word><Definition>saldiufhcnw</Definition></Entry> . . .

Then, encoding the XML data, including LZ77-encoding (step S404) and Huffman-encoding (step S406). When the XML data is LZ77-encoded (step S404), a bunch of codewords and literals are obtained, here the codewords are just the repeated literal “Word>” in the XML data, its length is 5, its distance, i.e. the space from the first “Word>” to the next “Word>”, is 12. The literals are just other literals that cannot be compressed, e.g. “Aback” and etc.

Performing Huffman-encoding to the XML data (step S406) to obtain codes of different lengths and generate Huffman list at the same time. For example, after Huffman-encoding the 20 literals ‘E’ ‘n’ ‘t’ ‘r’ ‘y’ ‘>’ ‘<’ ‘W’ ‘o’ ‘r’ ‘d’ ‘>’ ‘A’ ‘b’ ‘a’ ‘c’ ‘k ’ ‘<’ ‘/’, 20 codes of different lengths which are of hexadecimal are obtained: 6C 75 9E A4 A2 A9 6E 6C 87 9F A2 94 6E 71 92 91 93 9B 6C 5F.

Block-packing the Huffman-encoded XML data into several data blocks according to the Huffman table (step S408). For example, packing the words begin with the letter ‘A’ into one data block, and packing the words begin with the letter ‘B’ into the next data block, and so on, thus obtaining a number of data blocks.

Inserting the indicating data between the block-packed XML data blocks, (step S410) to obtain the compressed XML data (step S412). Said indicating data is for identifying particular data. Here the particular data mean the desired data, e.g. the word ‘car’.

Said indicating data is located in a null data block, at the block header of a null data block.

The compressed XML data is illustrated in table 1.

TABLE 1

| Data Block Number | Header | Contents |
|---|---|---|
| 0 | | 6C 75 9E A4 A2 A9 6E 6C 87 9F |
| | | A2 94 6E |
| 1 (Indicating Data | Huffman Table | Null |
| Block) | ‘0’ C | |
| | ‘1’ End of | |
| | Block | |
| 2 | | “Aback</[ . . . ]” = 71 92 91 |
| | | 93 9B 6C 5F . . . |
| 3 (Indicating Data | Huffman Table | Null |
| Block) | ‘0‘ E | |
| | ‘1’ End of | |
| | Block | |
| 4 | | “Car</[ . . . ]” = . . . |
| . . . | . . . | . . . |

It could be seen from table 1 that the contents comprised in data block 0 correspond to the encoded XML data “<Entry><Word>”, i.e. 6C 75 9E A4 A2 A9 6E 6C 87 9F A2 94 6E; data block 1, i.e. the block header of the indicating data block, is inserted with an indicating data ‘C’, and said data block is a null data block, without any data; data block 2 and data block 3 are similar to data blocks 0 and 1. Data block 4 contains words begin with the letter ‘C’. The contents of said data block are the literals corresponding to the word “Car”, i.e. literals similar to the aforementioned “6C 75” and etc.

FIG. 5 is a structural diagram of the decompression device of an embodiment of the present invention. The decompression device comprises a decompressor 500, a finite state machine (FSM) 510, an indicating data block detecting device 508 and an analyzer 512.

Decompressor 500 further comprises a block header decoder 502, a Huffman decoder 204 and a LZ77 decoder 206.

Block header decoder 502 is for block-header-decoding the compressed XML data block. During the block-header-decoding, each time a new data block is met, a data block signal will be generated and sent to finite state machine 510. Block header decoder 502 is further used for finding a null data block, and providing the null data block to indicating data block detecting device 508. Block header decoder 502 is also used for generating a Huffman list, and acts as a receiving device at the same time for receiving the compressed XML data.

Huffman decoder 204, for decoding the compressed block header decoded XML data according to the Huffman table.

LZ77 decoder 206, for LZ77-decoding the compressed XML data, obtaining the XML data. Said compressed XML data contains indicating data.

Indicating data block detecting device 508 is for obtaining the indicating data from the block header of the null data block provided by block header decoder 502 and sending it to analyzer 512. Said decompressor 500 and indicating data block detecting device 508 together form a data processing device for decompressing the compressed XML data.

Analyzer 512 modifies the contents of the indicating data based on a particular condition, generating a corresponding skip signal and sending it to finite state machine 510. Said particular condition corresponds to a particular application of analyzer 512, i.e. the data desired by analyzer 512, e.g. the word ‘car’. Modifying the indicating data may have two results, one is carrying out the contents of said indicating data, namely the corresponding skip signal requires finite state machine 510 to discard some irrelated data; the other is skipping over said indicating data, namely the contents of corresponding skip signal are null.

Finite state machine 510 discards the corresponding compressed XML data based on the data block signal and the modified indicating data contents, i.e. the skip signal. Said analyzer 512 and finite state machine 510 together form a discarding device for discarding the corresponding compressed XML data according to said indicating data.

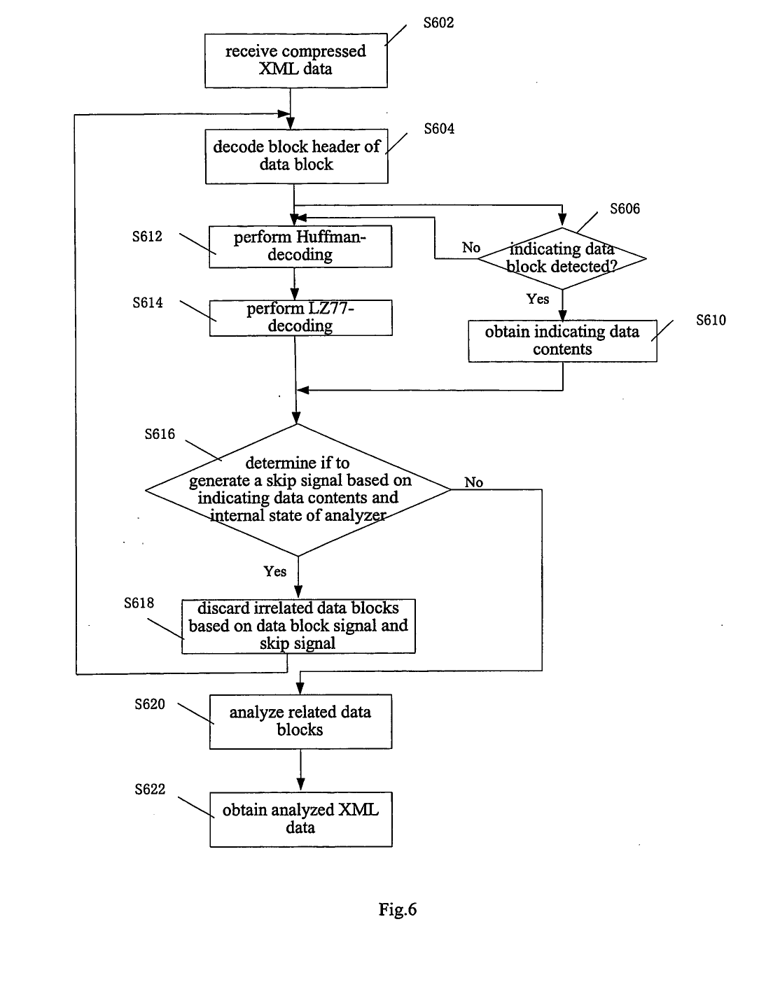

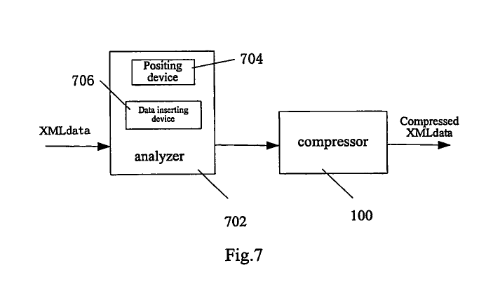

FIG. 6 is a flowchart of the decompression method of an embodiment of the present invention. First, receiving the compressed XML data (step S602), and said compressed XML data contains indicating data block.

Then decompressing the compressed XML data, including:

Block-header-decoding the compressed XML data (step S604) to find a null data block and generate data block signal, e.g. block-header-decoding the data block 1 will generate the data block signal of data block 1.

Detecting the indicating data block (step S606); if the indicating data block is detected, e.g. block-header-decoding the contents of data block 1, finding said data block to be null, it means that said data block is an indicating data block, then obtaining the contents of the indicating data from the block header of data block 1 (step S610), e.g. ‘C’.

If no indicating data block is detected in step S606, then detecting the next data block, i.e. data block 2; if it is found that data block 2 is not an indicating data block, Huffman-decoding it (step S612), and then LZ77-decoding it (step S614), thus obtaining the data of data block 2.

Whereafter, determining if to generate a skip signal according to the contents of the indicating data and the internal state of the analyzer, i.e. a particular condition (step S616), namely, modifying the contents of said indicating data based on a particular condition. Said particular condition is a particular application, i.e. the data desired by internal state of the analyzer, e.g. the word ‘car’, and then modifying the contents of the indicating data based on indicating data ‘C’, i.e. generating a skip signal, requiring to jump to part “C” directly.

Next, discarding the irrelated data blocks based on the data block signal and the skip signal (step S618), e.g. when in search of the word “Car”, determining that “Car” is a word began with the letter ‘C’ appearing in the data blocks behind, so a skip signal is generated to discard the irrelated data blocks, i.e. all the data (part “B”) of data block 2 before the appearance of the data block signal of data block 3 are discarded. Since the decompressed XML data is not of block structure, so each discarded data block needs to be controlled based on the data block signal.

In a similar way, obtaining the indicating data contents ‘E’ from the block header of data block 3 according to the method above (step S610), and obtaining the data of data block 4 (step S614), and then determining based on the indicating data ‘E’ and the word “Car”, which is being searched for (step S616). Since the word “Car” is before the word begin with the letter ‘E’, so no skip signal is generated. Then, analyzing the related data block, i.e. data block 4 (step S620), and in the end, obtaining the analyzed XML data, e.g. the word “Car”.

Here the discarding of the corresponding decompressed XML data is carried out according to the modified indicating data contents, i.e. the skip signal.

If the result of determining in step S616 is negative, it means that the discarding is not necessary, then directly analyzing the related data block (step S620), and obtaining the analyzed XML data (step S622).

FIG. 7 is a structural block diagram of the compression device of another embodiment of the present invention. The compression device comprises an analyzer 702 and a compressor 100.

Analyzer 702 further comprises a positioning device 704 for obtaining a group of useless data as the indicating data marks, and it acts as a receiving device at the same for receiving the XML data; a data inserting device for inserting corresponding indicating data behind a particular number of indicating data marks, and replacing the remaining indicating data marks with a group of useless data. The useless data is one of the following data: tab mark, space mark, enter mark and etc.

Compressor 100 compresses the XML data inserted with indicating data to obtain the compressed XML data.

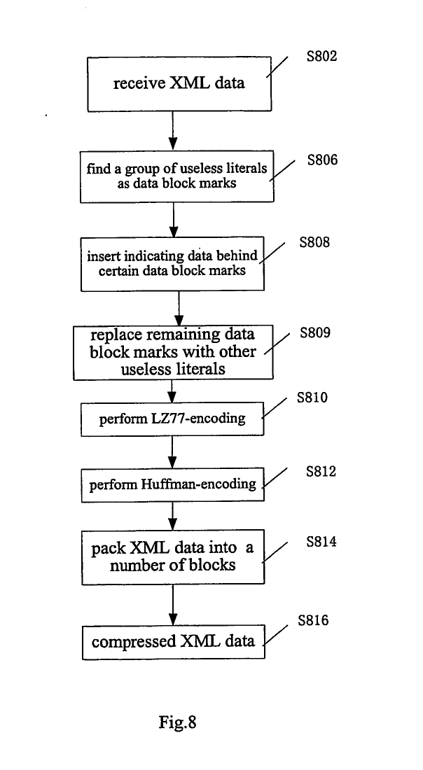

FIG. 8 is a flowchart of the compression method of another embodiment of the present invention. First, receiving the XML data (step S802), e.g. the XML data is:
<Entry><Word>→Aback</Word><Definition>saldiufhcnw</Definition></Entr y> . . .
<Entry><Word>→Car</Word><Definition>Izidnuvgrvgs</Definition></Entry > . . .

Then SAX-analyzing the XML data, finding a group of useless literals in the XML data, e.g. a group of 20 ‘→’ (tab mark), or space mark, enter mark and etc. Taking this group of useless literals ‘→’ as the indicating data marks (step S806).

Inserting indicating data behind a particular number, e.g. 14, of indicating data marks ‘→’ (step S808), e.g. ‘C’; then replacing the remaining. ‘→’ with other useless data (step S809), e.g. space. The obtained XML data is:
<Entry><Word>→<!--C-
>Aback</Word><Definition>saldiufhcnw</Definition></Entry> . . .
<Entry><Word>→<!--E--
>Car</Word><Definition>Izidnuvgrvgs</Definition></Entry> . . .

Here the XML data could be analyzed to obtain a group of useless data, e.g. ‘→’ (tab mark); then transforming the particular number of useless data into indicating data pack; putting the indicating data in the indicating data pack, and the XML data thus obtained is as stated above.

Thereafter, compressing the XML data containing indicating data, namely, LZ77-encoding the XML data containing indicating data (step S810); Huffman-encoding the LZ77-encoded XML data (step 812); packing the Huffman-encoded XML data into a number of data blocks (step S814); and in the end, obtaining the compressed XML data (step S816).

The indicating data and the data block marks as mentioned here are inserted into the XML data before the XML data is compressed. Here the inserted indicating data and data block marks are obvious to the decompression device. In other words, the decompression device will use them to skip over certain data, thus enhancing the function of the decompression device.

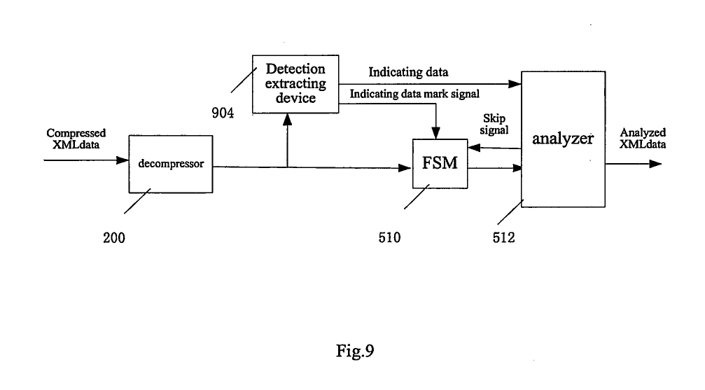

FIG. 9 is a structural block diagram of the decompression device of another embodiment of the present invention. Said decompression device comprises a decompressor 200, a detection extracting device 904, a finite state machine 510 and an analyzer 512.

Decompressor 200 decompresses the compressed XML data. The compressed XML data contains indicating data, wherein the indicating data is inserted in the original XML data. Decompressor 200 acts as a receiving device at the same time, for receiving the compressed XML data.

Detection extracting device 904 is used for finding a group of indicating data marks from the decompressed XML. data, obtaining said indicating data based on said indicating data marks, and sending said indicating data to analyzer 512. At the same time, detection extracting device 904 generates indicating data mark signal, and sends the indicating data mark signal to finite state machine 510. Decompressor 200 and detection extracting device 904 together form a data processing device.

Analyzer 512 modifies the contents of said indicating data based on a particular condition. Said particular condition is a particular application, i.e. the data desired by analyzer 512. Then the contents of said indicating data are modified, generating a corresponding skip signal, which is sent to finite state machine 510.

Finite state machine 510 discards the corresponding compressed XML data based on the indicating data mark signal and the modified indicating data contents, i.e. the skip signal. Said analyzer 512 and finite state machine 510 together form a discarding device for discarding the corresponding compressed XML data according to said indicating data.

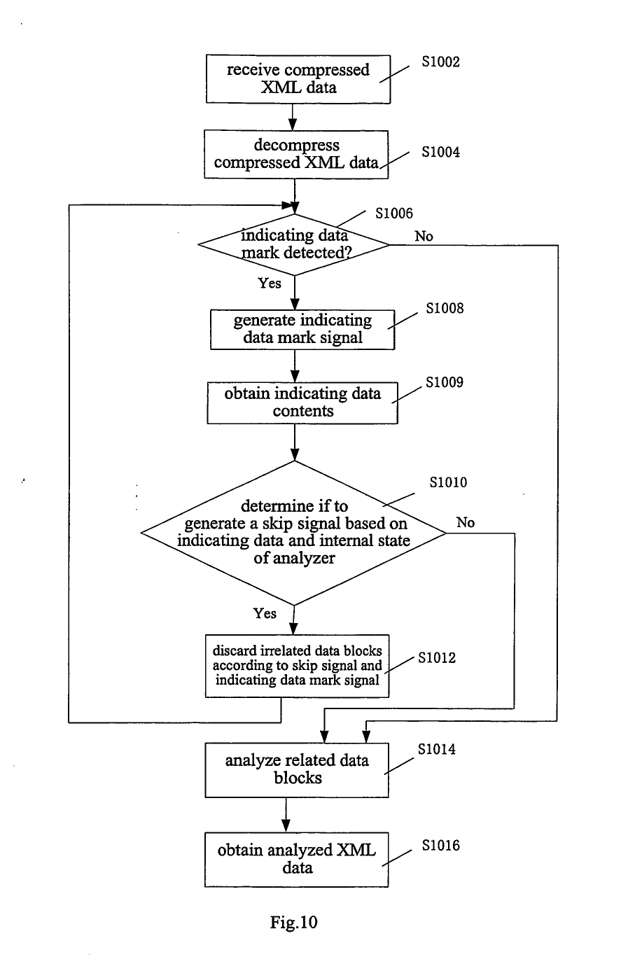

FIG. 10 is a flowchart of the decompression method of another embodiment of the present invention. First, receiving the compressed XML data (step S1002), then decompressing the compressed XML data (step S1004), obtaining the decompressed XML data.

An indicating data is obtained from said decompressed XML data, for identifying particular data. The specific steps are as below:

Detecting the indicating data marks, e.g. “→” in the XML data (step S1006), and if detected, then generating indicating data mark signal (step S1008).

Extracting the data-block-marked indicating data (step S1009), e.g. “C”.

Then, determining if to generate a skip signal based on the contents of the indicating data and the internal state of the analyzer, i.e. a particular condition (step S1010). Namely, modifying the contents of said indicating data based on a particular condition. In other words, determining if to generate a skip signal according to the indicating data “C” and a particular application, i.e. the data desired by the internal state of the analyzer. For example, when in search of the word ‘Car’, determining that “Car” is a word begin with the letter ‘C’ which appears in the data blocks behind, so a skip signal is generated to discard the irrelated data.

Next, if a skip signal requiring to discard data is generated in step S1010, discarding the irrelated data block according to the data block signal and the skip signal (step S1012), i.e. discarding all the data before the appearance of the next indicating data mark signal, and returning to step S1006 to continue detecting and determining.

In a similar way, when the next data block mark, i.e. the next “→”, is detected, obtaining the indicating data contents ‘E’ behind it according to the method above (step S1009). Determining if to generate a skip signal according to the indicating data “C” and a particular application, i.e. the data desired by the internal state of the analyzer (step S1010). For example, when in search of the word ‘Car’, determining that “Car” is before the words begin with the letter “E”, so no skip signal is generated. Then, analyzing the related XML data blocks (step S1014), and in the end, obtaining the analyzed XML data (step S1016), e.g. the word ‘car’.

Here the discarding of the corresponding decompressed XML data is carried out according to the modified indicating data contents, i.e. the skip signal.

If the result of determining in step S1006 or S1010 is negative, directly analyzing the related data blocks (step S1014), and obtaining the analyzed XML data (step S1016).

It could be seen from the embodiments of the present invention that, the analyzing process could be accelerated by avoiding analyzing the irrelated data blocks in the XML input data, and thus speeding up the operation at the receiving end. Since only the related part of the XML data is processed, the larger XML data input could be processed. All the XML information to be transmitted could be portioned into one small block of data in large XML data, thus being far better than processing one large block of data in a small XML data, because the former uses Zlib for compression much better than the later, thus saving bandwidth.

The present invention compresses relatively larger XML input data, so it will have better compression. Since the decompression device does not have to wait for information re-transmission, so the compressed XML data in the storage of the decompression device could provide comparatively faster access to the information.

Inserted with indicating data in the present invention is compatible with the existing compressing standard/scheme, such that the compressed XML data is compatible with the existing decompression device.

The present invention takes the indicating data and the XML data as one, so the indicating data can always match the contents of the XML data, even when the contents are being updated. The present invention does not need to allocate an additional transmission channel to the indicating data separately, thus saving the extra expense in transmitting data through a separate channel. Besides, when inserting the XML data, the indicating data is also compressed by the Zlib.

Although the present invention is described through specific embodiments, many substitutions, amendments and variations made according to the above text will be obvious to those ordinarily skilled in the art, so all these substitutions, amendments and variations shall be included in the present invention when they fall within the spirit and scope of the appended claims.

What is claimed is:

1. A method for compressing an XML data, comprising the steps of:
a. receiving the XML data;
b. encoding the XML data;
c. packetizing the encoded XML data;
d. inserting an indicating data between the block-packed XML data to obtain a compressed XML data, wherein the indicating data is used to identify specific data.

2. The method according to claim 1, wherein said indicating data is located in a null data block.

3. The method according to claim 2, wherein said indicating data is located in the block-head of the null data block.

4. A method for compressing an XML data, including the steps of:
a. receiving the XML data;
b. inserting an indicating data into the XML data, wherein the indicating data is used to identify an specific data;
c. compressing the XML data which contains the indicating data to obtain the compressed XML data.

5. The method according to claim 4, wherein step b includes the steps of:
analyzing said XML data to obtain a group of useless data as indicating data marks;
inserting the corresponding indicating data behind a specific number of the indicating data marks;
replacing remaining indicating data marks with another group of useless data.

6. The method according to claim 4, wherein step b including the steps of:
analyzing said XML data to obtain a group of useless data;
transforming a specific number of said useless data to an indicating data packet;
putting said indicating data into said indicating data packet.

7. The method according to claim 5 or 6, wherein said useless data is one of the following data: tabulation mark, blank mark and enter mark.

8. A method for decompressing an compressed XML data, comprising the steps of:
a. receiving the compressed XML data which contain an indicating data;
b. decompressing the compressed XML data, wherein this step includes step (i): obtaining said indicating data;
c. discarding the corresponding decompressed XML data according to the indicating data.

9. The method according to claim 8, wherein said indicating data is located in a null data block.

10. The decompressing method according to claim 8, wherein step (i) of step b comprises the steps of:
block-head-decoding said compressed XML data to find out a null data block;
obtaining the indicating data from the block-head of the null data block.

11. The decompressing method according to claim 8, further comprising the step of:
revising the content of the indicating data according to a specific condition, wherein step c is carried out according to the content of the revised indicating data.

12. The decompressing method according to claim 8, wherein said discarded XML data corresponds to specific data block in said compressed XML data.

13. A method for decompressing a compressed XML data, comprising the steps of:
a. decompressing the compressed XML data to obtain the decompressed XML data;
b. obtaining an indicating data from said decompressed XML data, wherein the indicating data is used to identify specific data;
c. discarding the corresponding decompressed XML data according to the indicating data.

14. The decompressing method according to claim 13, wherein said indicating data is inserted into the original XML data.

15. The decompressing method according to claim 13, wherein step b comprising the steps of:
finding out an indicating data mark in said XML data;
obtaining the indicating data according to the indicating data mark.

16. The decompressing method according to claim 13, further comprising the steps of:
revising the content of the indicating data according to a specific condition, wherein step c is carried out according to the revised content of the indicating data.

17. An apparatus for compressing an XML data, comprising:
receiving means for receiving the XML data;
encoding means for encoding the XML data;
packetizing means for packetizing the encoded XML data;
indicating data block inserting means for inserting the indicating data to between the block-packed XML data to obtain the compressed XML data, wherein the indicating data is used to identify the particular data.

18. The apparatus according to claim 17, wherein said indicating data is located in a null data block.

19. An apparatus for compressing an XML data, comprising:
receiving means for receiving the XML data;
indicating data packet inserting means for inserting the indicating data into the XML data, wherein the indicating data is used to identify the specific data;
compressing means for compressing the XML data in which the indicating data is inserted to obtain the compressed XML data.

20. The apparatus according to claim 19, wherein said indicating data pocket inserting means comprises:
positioning means for analyzing said XML data to obtain a group of useless data as the indicating data marks;
data inserting means for inserting the corresponding indicating data behind a specific number of indicating data marks, and replacing the remaining indicating data marks with another group of useless data.

21. The apparatus according to claim 20, wherein said useless data is one of the following data: tabulation mark, blank mark and enter mark.

22. An apparatus for decompressing an compressed XML data, comprising:
receiving means for receiving the compressed XML data, which contains an indicating data;
data processing means for decompressing the compressed XML data, and obtaining said indicating data;
discarding means for discarding the corresponding compressed XML data according to the indicating data.

23. The apparatus according to claim 22, wherein said indicating data is located in a null data block.

24. The apparatus according to claim 22, wherein said data processing means includes:
null data block detecting means for block-head-decoding the compressed XML data to find out a null data block;
indicating data obtaining means for obtaining the indicating data from the block-head of the null data block.

25. The apparatus according to claim 22, further comprising an analyzer for revising the content of the indicating data according to a specific condition, wherein said discarding means operates according to the revised content of the indicating data.

26. The apparatus according to claim 24, wherein said indicating data is inserted into an original XML data.

27. The apparatus according to claim 24, wherein said indicating data is obtained from the decompressed XML data.

28. The apparatus according to claim 24, wherein said data processing means includes a detecting result withdrawing means for finding out a group of indicating data marks from the decompressed XML data, and obtaining the indicating data according to the indicating data mark.
